(19) United States
(12) Patent Application Publication
(10) Pub. No.: US 2008/0265342 A1
(43) Pub. Date: Oct. 30, 2008

(54) TWO-BIT FLASH MEMORY CELL AND METHOD FOR MANUFACTURING THE SAME

(76) Inventors: Ming-Cheng Chang, Taipei County (TW); Wei-Ming Liao, Taipei City (TW); Jer-Chyi Wang, Taoyuan County (TW); Chien-Chang Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/780,482

(22) Filed: Jul. 20, 2007

(30) Foreign Application Priority Data
Apr. 24, 2007 (TW) 096114415

(51) Int. Cl. H01L 29/78

(52) U.S. Cl. 257/411; 257/E29.255

(57) ABSTRACT

A two-bit flash memory cell includes a substrate, a gate oxide layer disposed on the substrate, a T-shaped gate on the gate oxide layer. A first charge storage layer is disposed at one side of and under the T-shaped gate. A second charge storage layer, which is separated from the first charge storage layer by a bottom portion of the T-shaped gate and the gate oxide layer, is disposed at the other side of and under the T-shaped gate. An insulating layer is disposed between the T-shaped gate and the gate oxide layer. A first source/drain region is disposed at one side of the T-shaped gate within the substrate. A second source/drain region is disposed at the other side of the T-shaped gate within the substrate.

### BACKGROUND OF THE INVENTION

1. Field of the Invention

The present invention relates to flash memory and fabrication method thereof. More particularly, the present invention relates to two-bit, T-gated flash memory cell with sidewall storage and method for manufacturing the same

2. Description of the Prior Art

Non-volatile memory is computer memory that can retain the stored information even when not powered. Examples of non-volatile memory include flash memory and electically erasable programmable read only memory (EEPROM). Flash memory is non-volatile memory that can be electrically erased and reprogrammed. It is a technology that is primarily used in memory cards or USB flash drives, which are used for general storage and transfer of data between computers and other digital products. Unlike EEPROM, it is erased and programmed in blocks consisting of multiple locations (in early flash the entire chip had to be erased at once). Flash memory costs far less than EEPROM and therefore has become the dominant technology wherever a significant amount of non-volatile, solid-state storage is needed.

At present, the flash memory can be sub-classified into two types: stack gate flash memory and split gate flash memory. Generally, a stack gate flash memory cell includes a floating gate for storing charge, an oxide-nitride-oxide (ONO) dielectric layer and a control gate. The floating gate is between the control gate and the substrate. Because the floating gate is isolated by its insulating oxide layer, any electrons placed on it get trapped there and thus store the information.

FIG. 1 is a cross sectional view of a typical stack gate flash memory cell. As shown in FIG. 1, the flash memory cell 10a comprises a stack gate 14a on a P type semiconductor substrate 12a. An N type source 16a and an N type drain 18a are disposed on two sides of the stack gate 14a in the semiconductor substrate 12a. A P type doping region 20a is disposed under the N type drain 18a. The stack gate 14a comprises a tunnel oxide layer 22a, a floating gate 24a, an insulating layer 26a and a control gate 28a.

According to the prior art method, to program the flash memory 10a, a high voltage is applied to the control gate 28a and a fixed voltage is applied to the drain 18a. By doing this, channel hot electrons generated at the junction between the P type doping region 20a and the drain 18a are injected into the floating gate 24a through the tunnel oxide layer 22a. When electrons are on the floating gate 24a, they partially cancel out the electric field coupling from the control gate 28a, which modifies the threshold voltage (Vₜ) of the cell 10a. To erase the data stored in the flash memory 10a, the control gate 28a is typically connected to ground or negative voltages and the drain 16a is connected to a high voltage, thereby repelling the electrons in the floating gate 24a by Fowler-Nordheim tunneling mechanism.

FIG. 2 is a cross sectional view of a typical split gate flash memory cell 30a. As shown in FIG. 2, the flash memory cell 30a comprises a gate oxide layer 32a, a floating gate 34a, a control gate 38a, a drain 42a and a source 44a. The control gate 38a laterally extends to one side of the floating gate 34a to form a lower part between the source 44a and the floating gate 34a and a select gate channel 31a in the silicon substrate 40a. An insulating layer 36a is interposed between the control gate 38a and the floating gate 34a.

As the demand for the small size portable electronic devises such as PDA or mobile phones increases, there is constantly a strong need in this industry to provide high quality and high-density flash memory products, thereby improving the reliability and performance of the electronic products.

### SUMMARY OF THE INVENTION

It is one object of this invention to provide an improved two-bit flash memory structure in order to increase the integration of the flash memory device.

According to the claimed invention, a two-bit flash memory cell includes a semiconductor substrate; a gate oxide layer on the semiconductor substrate; a T-gate on the gate oxide layer; a first sandwich dielectric structure inlaid into one sidewall of the T-gate, the first sandwich dielectric structure comprising a first charge storage layer; a second sandwich dielectric structure inlaid into the other sidewall of the T-gate, the second sandwich dielectric structure comprising a second charge storage layer and being separated from the first sandwich dielectric structure by the T-gate and the gate oxide layer; an insulating layer between the T-gate and the first, second sandwich dielectric structures; a first source/drain doping region implanted in the semiconductor substrate next to the first sandwich dielectric structure; and a second source/drain doping region implanted in the semiconductor substrate next to the second sandwich dielectric structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross sectional view of a typical stack gate flash memory cell.

FIG. 2 is a cross sectional view of a typical split gate flash memory cell.

FIGS. 3-9 are schematic, cross-sectional diagrams showing the process for manufacturing a two-bit flash memory cell according to the preferred embodiment of this invention.

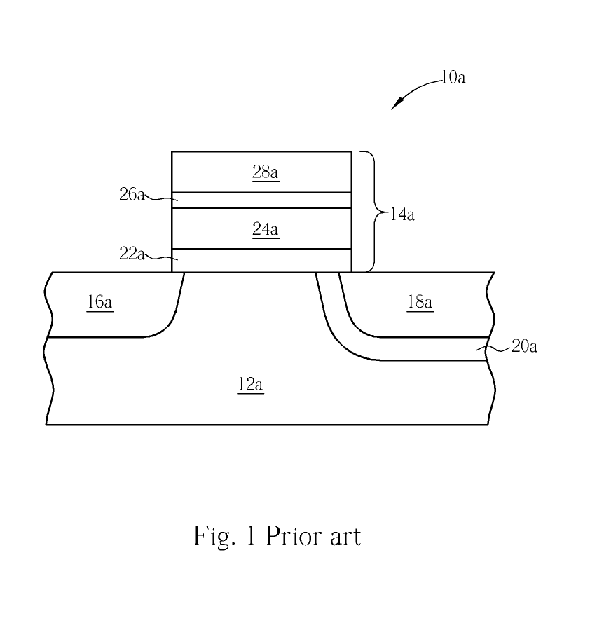

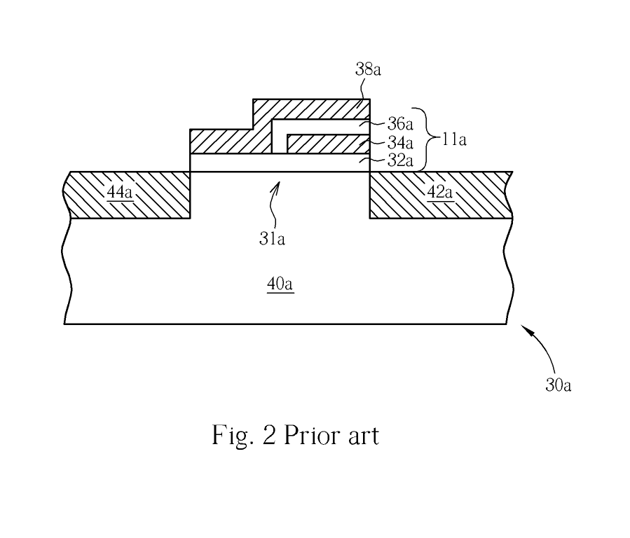

### DETAILED DESCRIPTION

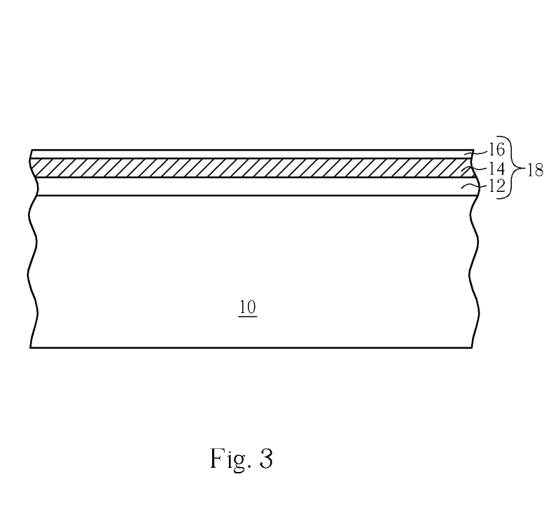

FIGS. 3-9 are schematic, cross-sectional diagrams showing the process for manufacturing a two-bit flash memory cell according to the preferred embodiment of this invention. As shown in FIG. 3, a semiconductor substrate 10 is provided. The semiconductor substrate 10 may be silicon substrate, silicon-on-insulator (SOI) substrate, SiGe semiconductor substrate or the like.

A liner layer 12 is formed on the surface of the semiconductor substrate 10. The liner layer 12 may be silicon oxide layer. Subsequently, a silicon nitride layer 14 is deposited on the liner layer 12.

The silicon nitride layer 14 may be made of high dielectric constant (high k or k>3.9) dielectric materials, for example, ZrO₂, HfO₂, Ta₂O₅, BaTiO₃, Zr silicate, Hf silicate, Al doped Zr silicate. By way of example, the Zr silicate may include (ZrO₂)ₓ(SiO₂)_{y}, Hf silicate may include (HfO₂)ₓ(SiO₂)_{y}, Al doped Zr silicate may include (ZrO₂)(Al₂O₃)ₓ(SiO₂)_{y}.

A dielectric layer 16 is formed on the silicon nitride layer 14. The dielectric layer 16 may be silicon oxide layer or silicon oxy-nitride layer. The liner layer 12, the silicon nitride layer 14 and the dielectric layer 16 constitute a dielectric stack structure 18.

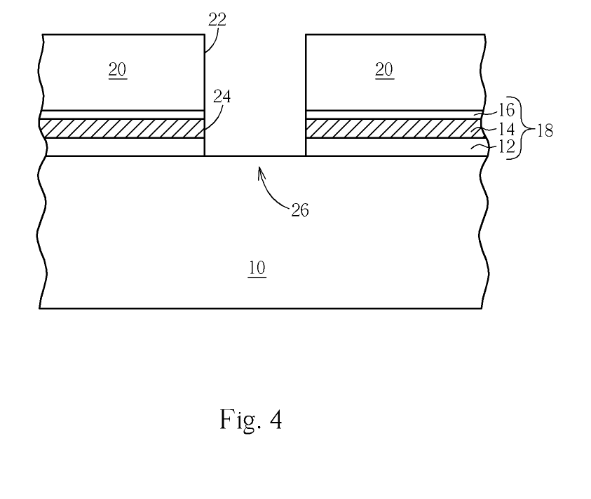

As shown in FIG. 4, a lithographic process is carried out to form a photoresist layer 20 on the dielectric layer 16. The photoresist layer 20 includes an opening 22 that defines the channel region 26 of the two-bit flash memory cell of this invention.

Subsequently, using the photoresist layer 20 as an etching hard mask, a dry etching process is carried out. The dielectric layer 16, the silicon nitride layer 14 and the liner layer 12 are consecutively etched away through the opening 22, thereby forming an opening 24 in the dielectric stack structure 18. The photoresist layer 20 is then stripped off.

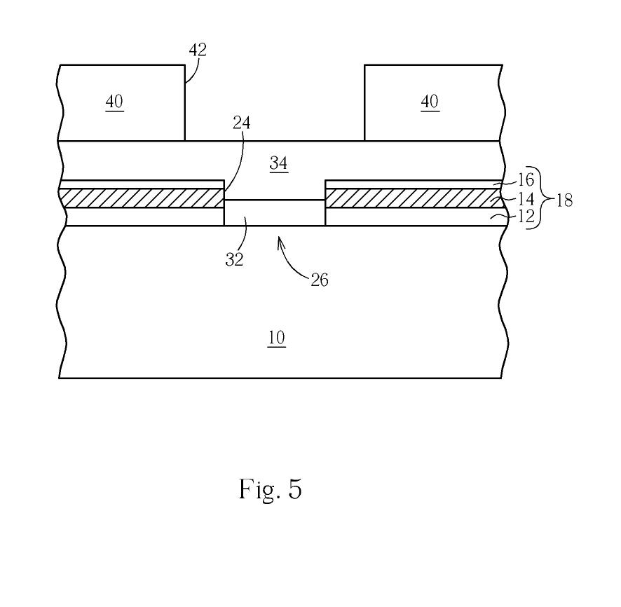

As shown in FIG. 5, an oxidation process is performed to form a gate oxide layer 32 on the semiconductor substrate 10 within the opening 24. According to the preferred embodiment of this invention, the gate oxide layer 32 has a thickness that is smaller than the thickness of the dielectric stack structure 18. Preferably, the thickness of the gate oxide layer 32 is thicker than that of the liner layer 12.

Thereafter, a dielectric layer 34 is formed on the dielectric stack structure 18 and on the gate oxide layer 32. The dielectric layer 34 fills the opening 24. The dielectric layer 34 may be composed of silicon oxide, silicon nitride or other dielectric materials, preferably silicon nitride.

Another lithographic process is then carried out to form a photoresist layer 40 on the dielectric layer 34. The photoresist layer 40 has an opening 42 that defines the position of the T-shaped gate (T-gate) of the two-bit flash memory cell of this invention.

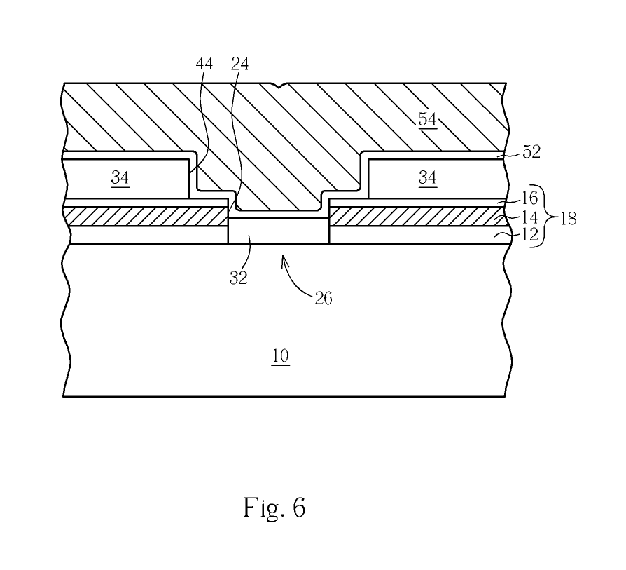

As shown in FIG. 6, a dry etching process is performed to etch the dielectric layer 34 through the opening 42 of the photoresist layer 40, thereby forming an opening 44 that exposes the gate oxide layer 32. The photoresist layer 40 is then stripped off.

A conformal oxide-nitride-oxide (ONO) dielectric layer 52 is formed on the dielectric layer 34, on the interior surfaces of the openings 44 and 24, and also on the gate oxide layer 32. Subsequently, a chemical vapor deposition (CVD) process is performed to deposit a polysilicon layer 54 on the ONO dielectric layer 52. The polysilicon layer 54 fills the openings 44 and 24.

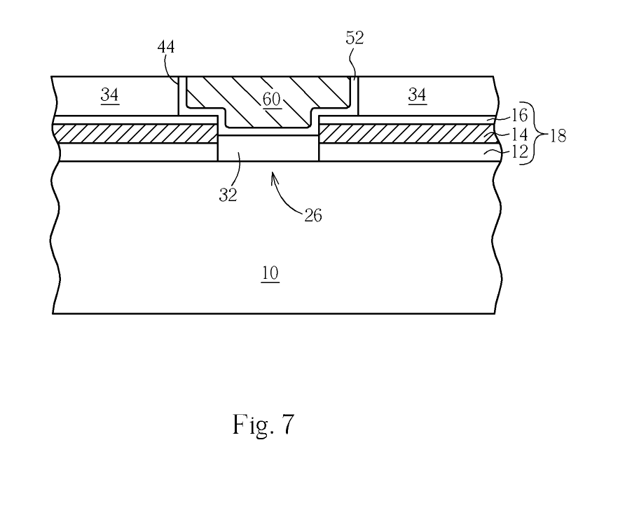

As shown in FIG. 7, using the dielectric layer 34 as a polishing stop layer, a chemical mechanical polishing (CMP) process is carried out to polish the polysilicon layer 54 and the ONO dielectric layer 52 above the dielectric layer 34 and the polysilicon layer 54 outside the opening 44. After the CMP, a T-shaped gate or T-gate 60 is inlaid in the openings 44 and 24.

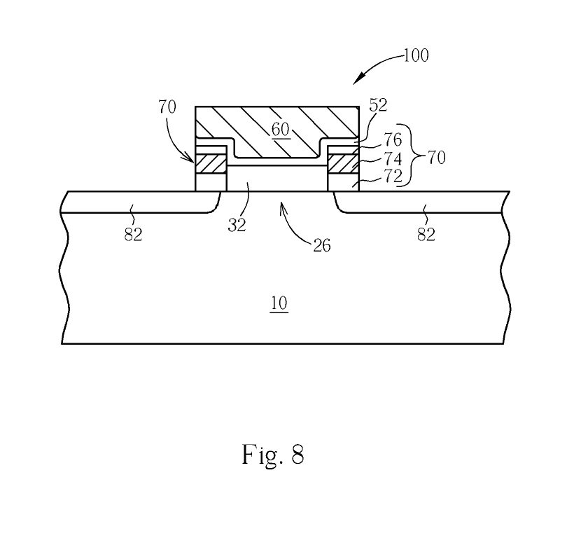

As shown in FIG. 8, using the T-gate 60 as a hard mask, an anisotropic dry etching process is performed to etch the ONO dielectric layer 52 not covered by the T-gate 60, the dielectric layer 34, and the dielectric stack structure 18 in a self-aligned fashion, thereby forming gate structure 100 of the flash memory cell.

At this point, sandwich dielectric structures 70 are embedded into two sides of the T-gate 60. The sandwich dielectric structures 70 are separated by the T-gate 60 and the gate oxide layer 32. Preferably, the sandwich dielectric structure 70 comprises a bottom dielectric layer 72, a charge storage layer 74 and an upper dielectric layer 76. The ONO dielectric layer 52 is interposed between the T-gate 60 and the sandwich dielectric structures 70. The charge storage layer 74 may be composed of silicon nitride or high-k dielectric (k>3.9) materials such as ZrO₂, HfO₂, Ta₂O₅, BaTiO₃, Zr silicate, Hf silicate, Al doped Zr silicate. By way of example, the Zr silicate may include (ZrO₂)ₓ(SiO₂)_{y}, Hf silicate may include (HfO₂)ₓ(SiO₂)_{y}, Al doped Zr silicate may include (ZrO₂)(Al₂O₃)ₓ(SiO₂)_{y}.

Thereafter, an ion implantation process is performed, using the gate structure 100 as an implant mask, to implant N or P type dopants into the semiconductor substrate 10 next to the sandwich dielectric structure 70, thereby forming lightly doped drain (LDD) regions 82. A channel region 26 is between the LDD regions 82. The post treatment includes thermal drive-in and activation of dopants. Preferably, the LDD region 82 partially overlaps with the sandwich dielectric structure 70 after the post treatment.

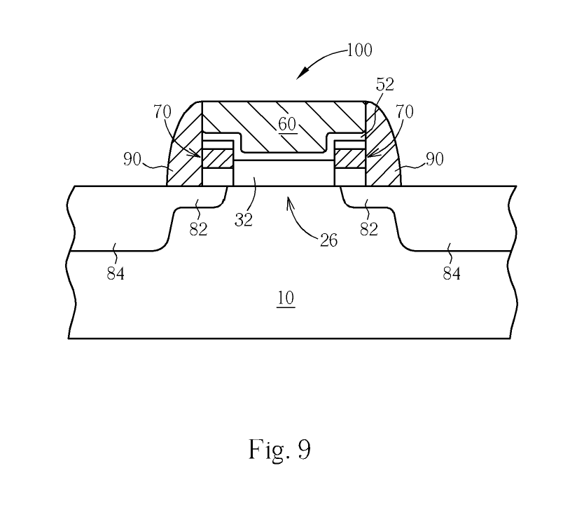

As shown in FIG. 9, spacers 90 are formed on sidewalls of the T-gate 60. The spacers 90 may be silicon nitride spacers or silicon oxide spacers. Finally, another ion implantation process is carried out, using the gate structure 100 and the spacers 90 as an implant mask, to implant N or P type dopants into the semiconductor substrate 10, thereby forming heavily doped source/drain regions 84.

Those skilled in the art will readily observe that numerous modifications and alterations of the device and method may be made while retaining the teachings of the invention.

What is claimed is:

1. A two-bit flash memory cell, comprising:
a semiconductor substrate;
a gate oxide layer on the semiconductor substrate;
a T-gate on the gate oxide layer;
a first sandwich dielectric structure inlaid into one sidewall of said T-gate, said first sandwich dielectric structure comprising a first charge storage layer;
a second sandwich dielectric structure inlaid into the other sidewall of said T-gate, said second sandwich dielectric structure comprising a second charge storage layer and being separated from said first sandwich dielectric structure by said T-gate and said gate oxide layer;
an insulating layer between said T-gate and said first, second sandwich dielectric structures;
a first source/drain doping region implanted in said semiconductor substrate next to said first sandwich dielectric structure; and
a second source/drain doping region implanted in said semiconductor substrate next to said second sandwich dielectric structure.

2. The two-bit flash memory cell of claim 1 wherein said first and second sandwich dielectric structures and said T-gate constitute vertical sidewalls.

3. The two-bit flash memory cell of claim 1 wherein said T-gate is composed of polysilicon.

4. The two-bit flash memory cell of claim 1 wherein said first sandwich dielectric structure comprises a first bottom dielectric layer, said first charge storage layer and a first upper dielectric layer.

5. The two-bit flash memory cell of claim 1 wherein said second sandwich dielectric structure comprises a second bottom dielectric layer, said second charge storage layer and a second upper dielectric layer.

6. The two-bit flash memory cell of claim 1 wherein said first and second charge storage layers are composed of silicon nitride.

7. The two-bit flash memory cell of claim 1 wherein said first and second charge storage layers are composed of ZrO₂, HfO₂, Ta₂O₅, BaTiO₃, Zr silicate, Hf silicate or Al doped Zr silicate.

8. The two-bit flash memory cell of claim 1 further comprising a spacer on said T-gate and said first, second sandwich dielectric structures.

9. The two-bit flash memory cell of claim 1 wherein said insulating layer is oxide-nitride-oxide (ONO) dielectric layer.

10. A two-bit flash memory cell, comprising:
a semiconductor substrate;
a gate oxide layer on the semiconductor substrate;
a T-gate on the gate oxide layer;
a first charge storage layer inlaid into one side of said T-gate;
a second charge storage layer inlaid into the other side of said T-gate, said second charge storage layer being separated from said first charge storage layer by said T-gate and said gate oxide layer;
an insulating layer between said T-gate and said gate oxide layer;
a first source/drain doping region implanted in said semiconductor substrate at one side of said T-gate; and
a second source/drain doping region implanted in said semiconductor substrate at the other side of said T-gate.

11. The two-bit flash memory cell of claim 10 wherein said T-gate is composed of polysilicon.

12. The two-bit flash memory cell of claim 10 wherein said first and second charge storage layers are composed of silicon nitride.

13. The two-bit flash memory cell of claim 10 wherein said first and second charge storage layers are composed of ZrO₂, HfO₂, Ta₂O₅, BaTiO₃, Zr silicate, Hf silicate or Al doped Zr silicate.

14. The two-bit flash memory cell of claim 10 wherein said insulating layer is oxide-nitride-oxide (ONO) dielectric layer.
